(19) United States
(12) Patent Application Publication
(10) Pub. No.: US 2014/0191273 A1
(43) Pub. Date: Jul. 10, 2014

(54) Light-emitting arrangement

(71) Applicants: Ties Van Bommel, Horst (NL); Rifat Ata Mustafa Hikmet, Eindhoven (NL)

(72) Inventors: Ties Van Bommel, Horst (NL); Rifat Ata Mustafa Hikmet, Eindhoven (NL)

(73) Assignee: KONINKLIJKE PHILIPS N.V., EINDHOVEN (NL)

(21) Appl. No.: 14/241,496

(22) PCT Filed: Aug. 17, 2012
(86) PCT No.: PCT/IB2012/054195

§ 371 Date: Feb. 27, 2014

Related U.S. Application Data
(60) Provisional application No. 61/532,594, filed on Sep. 9, 2011.

(51) Int. Cl. H01L 33/50

(52) U.S. Cl. CPC H01L 33/505; H01L 33/507
USPC 257/98

(57) ABSTRACT

A light emitting arrangement is provided, comprising:—a light source capable of emitting light of a first wavelength range;—a primary wavelength converting domain arranged to receive light emitted by said light source and capable of converting at least part of the light of said first wavelength range into light of a second wavelength range;—a secondary wavelength converting domain arranged to receive ambient light and capable of converting light into light of a third wavelength range from 470 nm to less than 570 nm, wherein said primary wavelength converting domain is arranged between said light source and said secondary wavelength converting domain; and—an optical element arranged in the path of light between said primary and secondary wavelength converting domains. By using the suggested arrangement a desirable off-state green or greenish appearance is obtained, using minor amounts of phosphor and with high light extraction efficiency.

### FIELD OF THE INVENTION

The invention relates to a light-emitting arrangement comprising wavelength converting domains.

### BACKGROUND OF THE INVENTION

Semiconductor-based based illumination devices are increasingly used for a wide variety of lighting applications, including general and decorative lighting applications. For example, light-emitting diodes (LEDs) offer advantages over traditional light sources, such as incandescent and fluorescent lamps, including long lifetime, high lumen efficacy, low operating voltage and fast modulation of lumen output.

Efficient high-power LEDs are often based on blue light emitting materials. To produce an LED based illumination device having a desired color (e.g., white) output, a suitable wavelength converting material, commonly known as a phosphor, may be used which converts part of the light emitted by the LED into light of longer wavelengths so as to produce white light. For instance, the light source may comprise a blue LED with one or more luminescent materials to provide white or whitish light (a color point on or near the black body line). Alternatively, the light source may comprise a UV (or Violet) LED with one or more luminescent materials, to provide white light. The wavelength converting material may be applied directly on the LED die, may be embedded in a LED dome, or it may be arranged at a certain distance from the LED (so-called remote phosphor designs).

A disadvantage of current LED-phosphor based illumination devices is that in the functional off-state of the device, the color of the phosphor may be clearly visible. For example, the commonly used phosphor YAG:Ce has a distinct yellowish appearance, which may be unappealing in many applications. Techniques have been developed to produce LED based illumination devices having a neutral, e.g. white or whitish, appearance also in the off-state. One such technique is disclosed in WO 2010/106478, which describes a color adjusting arrangement comprising a complementary phosphor that is capable of converting ambient light into light of a wavelength range that is complementary to the color of the conventional main phosphor.

However, in spite of the disclosure of WO 2010/106478, there remains a need for improved light emitting arrangements that provide a desirable color appearance and/or output light.

### SUMMARY OF THE INVENTION

It is an object of the present invention to overcome this problem, and to provide a light emitting arrangement having a green or greenish color appearance in the functional off-state.

According to a first aspect of the invention, this and other objects are achieved by a light emitting arrangement comprising:
a light source, preferably selected from an LED, an OLED and a laser diode, capable of emitting light of a first wavelength range;
a primary wavelength converting domain arranged to receive light emitted by said light source and capable of converting at least part of the light of said first wavelength range into light of a second wavelength range;
a secondary wavelength converting domain, arranged to receive ambient light and capable of converting light, optionally of said first wavelength range, into light of a third wavelength range which ranges from 470 nm to less than 570 nm, wherein said primary wavelength converting domain is arranged between said light source and said secondary wavelength converting domain; and
an optical element arranged in the path of light between said primary and secondary wavelength converting domains.

Advantageously, due to the combination of at least two wavelength converting domains and an optical element placed in between, and the outermost (secondary) wavelength converting domain comprising a green or greenish material, a desirable off-state green or greenish appearance is obtained, using minor amounts of phosphor and with high system efficacy (light extraction efficiency).

In embodiments of the invention the wavelength converting domains and said optical element may be arranged at a remote location in relation to the light source.

The first wavelength range may be from about 200 to 490 nm, preferably from 400 to 490 nm. Thus, the light source may be a blue light emitting light source.

The second wavelength range may be in the wavelength range of from 500 to 800 nm, for example from 550 to 800 nm, and typically from 570 to 800 nm. Hence, the primary wavelength converting domain may comprise a yellow, orange and/or red luminescent material.

In embodiments of the invention the secondary wavelength converting domain may comprise an organic wavelength converting material, for example comprising a perylene or perylene derivative. Alternatively or additionally, said primary wavelength converting domain may comprise an organic wavelength converting material, for example comprising a perylene or perylene derivative. Organic phosphors in general have the advantage that their luminescence spectrum can be easily adjusted with respect to position and band width of absorption and emission band by designing the structure of the organic molecule. Organic phosphor materials also often have a high degree of transparency, which is advantageous since the efficiency of a lighting system may then be improved compared to systems using more light-absorbing and/or reflecting phosphor materials. Organic phosphors have high quantum efficiency, and thus much smaller amounts of organic phosphor may be used compared to inorganic phosphors. Furthermore, organic phosphors are more environmentally sustainable than inorganic phosphors, in particular because their manufacture does not require rare earth minerals.

Alternatively, in embodiments of the invention the primary and/or the secondary wavelength converting domain(s) may comprise quantum dots. Quantum dots show very narrow emission band and thus show saturated colors. Furthermore the emission color can easily be tuned by adapting the size of the quantum dots.

In embodiment of the invention, the primary and/or the secondary wavelength converting domain may comprise a carrier material, e.g. polymeric carrier.

In embodiments of the invention, the optical element is a diffuser, preferably comprising scattering elements dispersed in a carrier.

For example, the optical element may comprise a plurality of diffusers arranged sequentially in the path of light between the first domain and the second domain, which may further reduce the visibility of the primary wavelength converting domain.

Alternatively, the optical element may comprise a plurality of individual diffuser elements arranged in plane and mutually spaced apart. Advantageously, such a discontinuous or patterned diffuser may reduce backscattering of light towards the LED and hence improve system efficacy.

In embodiments of the invention, the optical element may comprise a prismatic structure and/or a brightness enhancement film.

Typically, the primary wavelength converting domain and/or the secondary wavelength converting domain comprises, in addition to the respective wavelength converting material, non-converting scattering particles. By including scattering materials in the wavelength converting domain the path length of the light within the wavelength converting domain may be increased, thus increasing the amount of light converted. Alternatively, a lower amount of wavelength converting material may be used to achieve an acceptable result.

In embodiments of the invention, the primary wavelength converting domain and the optical element, and/or the optical element and the secondary wavelength converting domain, are in direct optical contact. When the diffuser is in direct optical contact with either or both of the wavelength converting domains the efficacy of the system is improved, but without resulting in unacceptably high visibility of the primary wavelength converting domain. When the optical element is not in direct optical contact with the secondary wavelength converting domain. more ambient light is absorbed and reflected by the secondary wavelength converting domain.

In another aspect, the invention provides a luminaire comprising at least one light emitting arrangement as described herein.

It is noted that the invention relates to all possible combinations of features recited in the claims.

### BRIEF DESCRIPTION OF THE DRAWINGS

This and other aspects of the present invention will now be described in more detail, with reference to the appended drawings showing embodiment(s) of the invention.

FIG. 1 shows a light-emitting arranged according to embodiments of the invention; and

FIG. 2a-2e schematically illustrate different principles for arranging the first and second wavelength converting domains and the optical element according to other embodiments of the light emitting arrangement of the invention.

### DETAILED DESCRIPTION

The present inventors have found that a light-emitting arrangement comprising a primary wavelength converting domain, a green or greenish secondary wavelength converting domain and an optical element arranged in between, may provide a desirable off-state color appearance while maintaining system efficacy and potentially using more environmentally acceptable materials.

As used herein, “light” means UV and visible electromagnetic radiation. By “ambient light” is meant the UV and visible radiation originating from the surroundings of a light-emitting arrangement.

As used herein, “optical contact” refers to a path of light extending from one object to another object where said objects are in optical contact. “Direct optical contact” is intended to mean that said light may pass from the first object to the second object without having to pass through an intermediate medium such as air or another object.

As used herein, “wavelength converting material” refers to a composition of matter which is capable of converting light of one wavelength or wavelength range into light of another wavelength or wavelength range. “Phosphor” refers to an organic or inorganic material having said wavelength conversion capability.

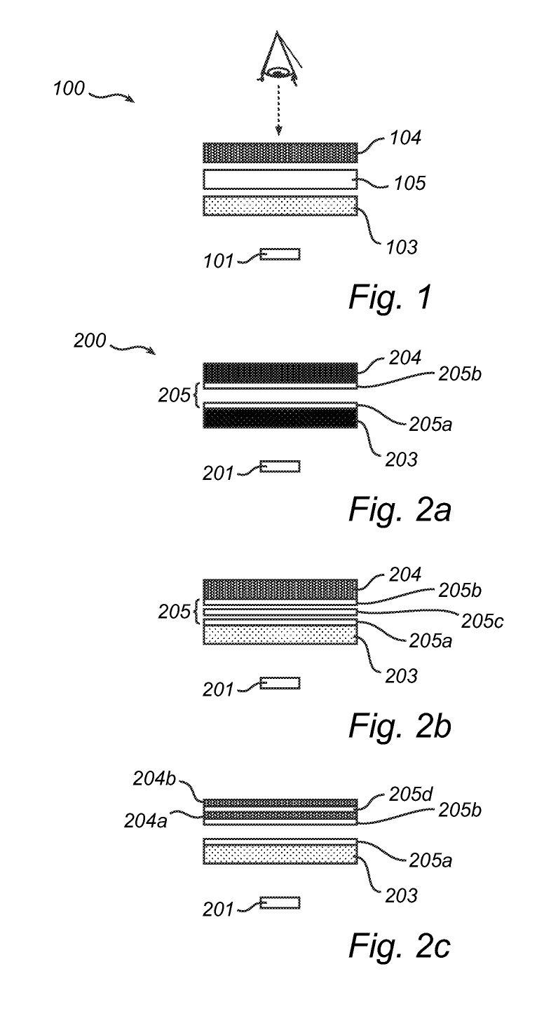

FIG. 1 illustrates the general structure of a light emitting arrangement according to embodiments of the invention. The light emitting arrangement 100 comprises a light source 101 typically provided on a substrate (not shown). The light source is adapted to emit light in a light output direction corresponding to upwards in the figure, in the direction of a viewer (and away from the substrate). In the path of light from the light source, but at a distance from it, is arranged in this order a primary wavelength converting domain 103, an optical element 105 in the form of a diffuser, and a secondary wavelength converting domain 104.

During operation of the light-emitting arrangement, the light source 101 emits light of a first wavelength range in the direction of the primary wavelength converting domain 103. It is envisaged that portions of the light source, the substrate surface around the light source and/or any walls (not shown) surrounding the light source may be reflective in order to efficiently recycle light that is not directly absorbed (converted) by or transmitted through the primary wavelength converting domain. The primary wavelength converting domain 103 comprises a wavelength converting material which is capable of converting at least part of the light emitted by the light source. In a preferred embodiment, the light source is a blue-emitting LED and the first wavelength converting material is capable of converting blue light into light in the yellow-orange-red spectral region. Some blue light is transmitted by the primary wavelength converting domain without being converted, and is mixed with the converted light.

Moreover, the secondary wavelength converting domain 104 comprises a second wavelength converting material which is capable of converting light of wavelengths of <500 nm, typically up to 480 nm, into green or greenish light, typically 470-570 nm, preferably 490-5760 nm, for example 500-560 nm or 510-560 nm. Thus, during operation of the light-emitting arrangement, the secondary wavelength converting domain way convert part of the light that is emitted by the light source and transmitted by the first domain. The secondary wavelength converting domain typically transmits light of the second wavelength range.

During operation the secondary wavelength converting domain receives light emitted by the light source that has not been converted by the first wavelength converting material, but only transmitted by the primary wavelength converting domain (and scattered by the diffuser 105). The second wavelength converting material typically converts a part of the light emitted by the light source into green or greenish light.

Thus, the outgoing light that is observed by a viewer during operation of the light emitting arrangement is a mixture of light emitted by the light source 101 (first wavelength range), light converted by the primary wavelength converting domain 103 (second wavelength range), and light converted by the secondary wavelength converting domain 104 (green or greenish). Typically, the light source, and the first and second wavelength converting materials may be selected such that the resulting mixture of light of different wavelengths is perceived as white light, having a correlated color temperature on or near the black body line, preferably on the black body line.

In the functional off-state, i.e. when the light source does not emit light, the light emitting arrangement 100 typically has a green or greenish appearance. Ambient light incident on the secondary wavelength converting domain may be absorbed, reflected and/or converted by the secondary wavelength converting domain. Typically, part of ambient light of the first wavelength range may be converted into green or greenish light. Ambient light of some wavelengths, typically the green spectral range, may be reflected. Typically, reflected ambient light provides the major contribution to the color appearance. Ambient light incident on the secondary wavelength converting domain 104 that is not converted or reflected may either be absorbed, or transmitted through the secondary wavelength converting domain and subsequently scattered by the optical element 105. Typically, very little ambient light of the first wavelength range reaches the primary wavelength converting domain 103. As a result, the light exiting the light emitting arrangement in the functional off-state has a generally green or greenish appearance.

By using the suggested arrangement comprising a primary wavelength converting domain, a green or greenish secondary wavelength converting domain and an optical element arranged in between, a desirable off-state green or greenish appearance is obtained, using minor amounts of phosphor and with high system efficacy (light extraction efficiency).

In embodiments of the present invention, the light source may be a semiconductor based device, typically an LED, an OLED or a laser diode. The light source may comprise a plurality of such devices, in particular a plurality of LEDs.

The first wavelength range emitted by the light source during operation thereof may be from about 200 to 490 nm, preferably from 400 to 480 nm.

The first wavelength converting domain may comprise one or more wavelength converting material(s) capable of converting light of the first wavelength range, such as blue light, into light in of the orange-to-red spectral region. Thus the second wavelength range, emitted by a first wavelength converting material, or by a combination of wavelength converting materials, may correspond to a wavelength range of 500 to 800 nm, typically 550 to 800 nm, for example 570 to 800 nm and preferably 590 to 800 nm. The first wavelength converting material may comprise one or more inorganic phosphor materials, one or more organic materials, or a combination thereof.

Examples of inorganic phosphors suitable for the first wavelength converting material include, but are not limited to, cerium doped yttrium aluminum garnet (Y₃Al₅O₁₂:Ce³⁺, also referred to as YAG:Ce or Ce doped YAG) or lutetium aluminum garnet (LuAG, Lu₃Al₅O₁₂), α-SiAlON:Eu²⁺ (yellow), and M₂Si₅N₈:Eu²⁺ (red) wherein M is at least one element selected from calcium Ca, Sr and Ba.

A preferred example of an inorganic phosphor that may be used in embodiments of the invention, typically in combination with a blue light emitting light source, is YAG:Ce. Furthermore, a part of the aluminum may be substituted with gadolinium (Gd) or gallium (Ga), wherein more Gd results in a red shift of the yellow emission. Other suitable materials may include (Sr_{1-x-y}BaₓCa_{y})_{2-z}Si₅₋ₐAlₐN₈₋ₐOₐ:Eu_{z}²⁺ wherein 0≦a≦5, 0≦x≦1, 0≦y≦1 and 0<z<1, and (x+y)<1, such as Sr₂Si₅N₈:Eu²⁺ which emits light in the red range.

In embodiments of the invention, the first domain may contain an organic wavelength converting material, as an alternative to the inorganic phosphor as described above or in addition thereto.

Examples of organic materials suitable for use as the first wavelength converting material include luminescent materials based on perylene derivatives, which are for instance sold under the brand name Lumogen® by BASF. Examples of suitable commercially available products thus include, but are not limited to, Lumogen® Red F305, Lumogen® Orange F240, Lumogen® Yellow F170, and combinations thereof.

Optionally the primary wavelength converting domain may comprise scattering elements, e.g. particles of Al₂O₃ or TiO₂.

The second wavelength converting material, comprised in the secondary domain, may be an inorganic wavelength converting material, or an organic wavelength converting material. Optionally, the secondary wavelength converting domain may comprise two or more different wavelength converting materials.

The second wavelength converting material may be a phosphor having a green appearance, or a green-yellow appearance, or may be a combination of such phosphor materials. Examples of inorganic materials suitable for the second wavelength converting material include cerium doped lutetium aluminum garnet (LuAG, Lu₃Al₅O₁₂), which emits yellowish-green light. For example, cerium doped LuAG can be used for the second wavelength converting material while a red inorganic phosphor such as (BaSr)₂Si₅N₈:Eu²⁺ (BSSN) is used as the first wavelength converting material. However, it is also possible that the second wavelength converting material, used secondary wavelength converting domain is LuAG, while a combination of LuAG and BSSN is used in the primary wavelength converting domain.

Examples of organic materials suitable for use as the second wavelength converting material include perylene and derivatives such as F083 (BASF) with a green emission. Such materials can also be combined with other organic wavelength converting materials with relatively narrow absorption band in the orange part of the spectrum, such as pyrromethene dyes.

Optionally the secondary wavelength converting domain may comprise scattering particles e.g. Al₂O₃ or TiO₂.

The wavelength converting materials of the primary and secondary domains, respectively may be contained in a carrier material. For example, particles of inorganic wavelength converting material may be dispersed in a carrier, such as a polymeric material or silicone resin. In the case of an organic wavelength converting material, the material is preferably molecularly dissolved in the carrier.

In embodiments of the invention the wavelength converting material of the first domain and/or the wavelength converting material of the second domain may comprise quantum dots. Quantum dots are small crystals of semiconducting material generally having a width or diameter of only a few nanometers. When excited by incident light, a quantum dot emits light of a color determined by the size and material of the crystal. Light of a particular color can therefore be produced by adapting the size of the dots. Most known quantum dots with emission in the visible range are based on cadmium selenide (CdSe) with shell such as cadmium sulfide (CdS) and zinc sulfide (ZnS). Cadmium free quantum dots such as indium phosphode (InP), and copper indium sulfide (CuInS₂) and/or silver indium sulfide (AgInS₂) can also be used. Quantum dots show very narrow emission band and thus they show saturated colors. Furthermore the emission color can easily be tuned by adapting the size of the quantum dots. Any type of quantum dot known in the art may be used in the present invention, provided that it has the appropriate wavelength conversion characteristics. However, it may be preferred for reasons of environmental safety and concern to use cadmium-free quantum dots or at least quantum dots having a very low cadmium content.

The first and/or second wavelength converting materials, respectively, may be selected with respect to the correlated color temperature of the emitted light. Moreover, the first and the second wavelength converting material may be selected in combination so as to provide a desirable corrected color temperature of the (white) light emitted during operation.

Examples of suitable carriers comprise poly(ethylene terephthalate) (PET) and copolymers thereof, polyethylene naphthalate (PEN) and copolymers thereof, polystyrene (PS), polycarbonate (PC), silicone, polysiloxane such as poly(dimethyl siloxane) (PDMS), poly(methyl methacrylate) (PMMA) and acrylate polymers in general.

The primary and/or the secondary wavelength converting domain may form a film, sheet or layer, which may contain the respective wavelength converting material dispersed or dissolved therein. Such a film or sheet may have a thickness in the range of from 10 μm to 4 mm.

For example, the primary and/or the secondary wavelength converting domain may be formed of a film, sheet or layer having a thickness in the range of 100 to 400 μm. For example, a composition comprising a carrier material and the wavelength converting material may be extruded into a film, or printed (e.g. screen printed), bladed or spin-coated to form a layer having the desired thickness.

Alternatively, in applications where a rigid or mechanically stable structure is desired, the first and/or the second domain (in particular the second domain) may be a sheet or plate having a thickness in the range of from 1 to 4 mm, for example produced by injection molding from a composition comprising the carrier and the wavelength converting material.

The content of the first or second wavelength converting material, respectively, in the respective domain (e.g. a film) typically depends on whether the wavelength converting material is inorganic or organic. Furthermore, the thickness of the respective wavelength converting domain may also be taken into consideration. For organic wavelength converting materials contained in a thin polymeric film or layer, a suitable content of the wavelength converting material may be 1% or less by weight of the film or layer, for example 0.1% or less by weight, such as 0.01% or less by weight. For inorganic phosphor materials, a suitable content may be from 5 to 80% by weight of the wavelength converting domain. The concentration of wavelength converting material and the thickness of the domain (e.g. a film or layer) can be suitable adjusted to obtain the desired color point and the colored appearance.

In embodiments of the invention the light source and the wavelength converting domains are arranged mutually spaced apart, that is in so-called remote configuration. Hence, the phosphor is less exposed to the high operating temperature of the light source, and the degradation rate of the phosphor material, in particular an organic material, is reduced compared to a situation where the phosphor is arranged closer or directly adjacent to the light source.

Advantageously the first wavelength converting material is contained in the primary wavelength converting domain, and the second wavelength converting material is contained in the secondary wavelength converting domain. Thus, the first wavelength converting material and the second wavelength converting material may be spatially separated, which may reduce the risk of the first wavelength converting material absorbing light of the wavelength range emitted by the second wavelength converting material.

The optical element 105 may be a diffuser, e.g. comprising scattering elements dispersed in a carrier material, or a film or plate comprising a structured surface. The optical element may be in the form of a self-supporting film or plate, or may be applied as a layer on a surface of either one, or both, of the wavelength converting domains 103, 104. The carrier material of the optical element may be the same or different as the carrier material used in the primary wavelength converting domain and/or the secondary wavelength converting domain, where applicable. Examples of suitable carrier materials for use in a diffuser include the polymeric materials suggested above for the first and second domains, respectively.

For example, a diffuser, e.g. in the form of a scattering layer, may be arranged in the path of incident ambient light extending via the secondary wavelength converting domain to the primary wavelength converting domain, such that incident ambient light first reaches the secondary wavelength converting domain, subsequently reaches the diffuser, and lastly reaches the primary wavelength converting domain. Since some scattering materials, e.g. TiO₂, may compete with the second wavelength converting material for light absorption, it may be preferable to arrange the second wavelength converting domain such that the ambient light enters this domain before entering the scattering material. In this way the second wavelength converting material may be utilized more effectively.

Alternatively, the optical element may be a film or plate having a scattering surface structure or texture, e.g. a prismatic structure.

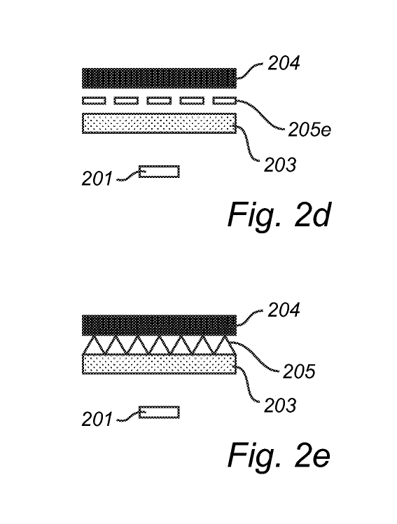

FIG. 2a-d schematically illustrates different principles for arranging the optical element and the wavelength converting domains according to further embodiments of the light-emitting arrangement. As illustrated in FIG. 2a, the optical element 205 may comprise two diffuser layers 205a and 205b, a first layer 205a arranged on the primary wavelength converting domain 203 and a second layer 205b arranged on the secondary wavelength converting domain 204, the diffuser layers facing one another. In another embodiment shown in FIG. 2b, an additional diffuser layer 205c, typically a film or a plate, may be arranged in between the first diffuser layer 205a and the second diffuser layer 205b. The additional layer 205c may further reduce the visibility of the primary wavelength converting domain.

Advantageously, the optical element 105, 205 may be arranged such that it is in direct optical contact with either the first domain, the second domain, or both. In the case where the optical element is formed of a plurality of layers, such as in FIG. 2a-c, it may be preferable that each wavelength converting domain is in direct optical contact with one such layer.

Furthermore, the respective positions and the thicknesses of the diffuser layers 205a, 205b may be used to adapt the correlated color temperature of the light emitted by the light-emitting arrangement during operation.

FIG. 2c illustrates yet another embodiment, in which an optical element 205 is arranged between the primary and secondary wavelength converting domains as in FIG. 2a, but in which additionally the first domain comprises two layers 204a, 204b comprising wavelength converting material, separated by an additional optical element 205d. The additional optical element 205d, typically a diffuser layer, may be in direct optical contact with either one of the wavelength converting layers 204a and 204b, or with both. Similarly to the embodiment of FIG. 2b, the provision of an additional diffuser layer 205d may reduce the visibility of the primary wavelength converting domain and increase the green or greenish color appearance of the light-emitting arrangement.

FIG. 2d illustrates a further embodiment, in which the optical element 205 has a discontinuous structure, e.g. being a layer having holes therethrough, or a pattern formed of separate layer portions, e.g. forming a grid pattern. Advantageously, a discontinuous or patterned diffuser may reduce backscattering of light towards the LED and hence improve system efficacy.

Finally, in an alternative embodiment illustrated in FIG. 2e, the optical element 205 may be a refractive element, e.g. comprising a prismatic structure or a brightness enhancement film (BEF, available from 3M).

Typically, the light emitting arrangements according to the invention may have a color rendering index (CRI) of at least 80.

The light-emitting arrangement according to the invention may be produced using conventional methods known to persons skilled in the art. For example, the wavelength converting domains may be produced by injection molding, extrusion, printing (e.g. screen printing), blading or coating (e.g. spin coating), optionally onto a sacrificial substrate, from a suitable composition comprising the wavelength converting material in question and typically a carrier material. The optical element may be produced using corresponding methods or other suitable methods known in the art.

The light-emitting arrangement as described herein may be used in a e.g. luminaire or lamp e.g. for general lighting applications for home or professional environment, decorative lighting for home or professional environment, exposition applications etc.

### EXAMPLE 1

In one example, the light emitting arrangement comprises a stack of: a blue LED light source having an emission peak wavelength (PWL) of 455 nm, a primary wavelength converting domain comprising BSSN in PMMA, a diffuser in the form of TiO₂ particles dispersed in PMMA; and a secondary wavelength converting domain comprising LuAG.

### EXAMPLE 2

In another example, the light emitting arrangement comprises a stack of: a blue LED light source having an emission a peak wavelength (PWL) of 450 nm, a primary wavelength converting domain comprising Lumogen® Red F305 (BASF) in PMMA; a diffuser in the form of TiO₂ particles dispersed in PMMA, and a secondary wavelength converting domain comprising LuAG.

### EXAMPLE 3

In another example, the light emitting arrangement comprises a stack of: a blue LED light source having an emission peak wavelength (PWL) of 445 nm, a primary wavelength converting domain comprising Lumogen® Red F305 and Lumogen® Orange F240 (BASF) in PMMA a diffuser in the form of TiO2 particles dispersed in PMMA, and a secondary wavelength converting domain comprising Lumogen® F083 (BASF).

The person skilled in the art realizes that the present invention by no means is limited to the preferred embodiments described above. On the contrary, many modifications and variations are possible within the scope of the appended claims.

1. A light emitting arrangement, comprising:
a light source capable of emitting light of a first wavelength range;
a primary wavelength converting domain arranged to receive light emitted by said light source and capable of converting at least part of the light of said first wavelength range into light of a second wavelength range;
a secondary wavelength converting domain, arranged to receive ambient light and capable of converting light, optionally of said first wavelength range, into green light of a third wavelength range which ranges from 470 nm to 570 nm, wherein said primary wavelength converting domain is arranged between said light source and said secondary wavelength converting domain; and
an optical element arranged in the path of light between said primary and secondary wavelength converting domains.

2. A light emitting arrangement according to claim 1, wherein said wavelength converting domains and said optical element are arranged at a remote location in relation to the light source.

3. A light emitting arrangement according to claim 1, wherein said first wavelength range is from about 200 to 490 nm.

4. A light emitting arrangement according to claim 1, wherein said secondary wavelength converting domain comprises an organic wavelength converting material.

5. A light emitting arrangement according to claim 1, wherein said second wavelength range is in the wavelength range of from 500 to 800 nm.

6. A light emitting arrangement according to claim 1, wherein said primary wavelength converting domain comprises an organic wavelength converting material.

7. A light emitting arrangement according to claim 1, wherein the primary and/or the secondary wavelength converting domain comprises a carrier material.

8. A light emitting arrangement according to claim 1, wherein the optical element is a diffuser, preferably comprising scattering elements dispersed in a carrier.

9. A light emitting arrangement according to claim 8, wherein the optical element comprises a plurality of diffusers arranged in the path of light between the first domain and the second domain.

10. A light emitting arrangement according to claim 8, wherein the optical element comprises a plurality of individual diffuser elements arranged in plane and mutually spaced apart.

11. A light emitting arrangement according to claim 1, wherein the optical element comprises a prismatic structure.

12. A light emitting arrangement according to claim 1, wherein the primary wavelength converting domain and/or the secondary wavelength converting domain comprises non-converting scattering particles.

13. A light emitting arrangement according to claim 1, wherein the primary wavelength converting domain and the optical element, and/or the optical element and the secondary wavelength converting domain, are in direct optical contact.

14. A light emitting arrangement according to claim 1, wherein in the functional off-state the light-emitting arrangement has a green or greenish appearance.

15. A luminaire comprising at least one light emitting arrangement according to claim 14.
